(19) United States
(12) Patent Application Publication
(10) Pub. No.: US 2011/0001154 A1
(43) Pub. Date: Jan. 6, 2011

(54) Method of preparing an oxynitride phosphor, oxynitride phosphor obtained using the method, and a white light-emitting device including the oxynitride phosphor

(75) Inventors: Tae-gon Kim, Seoul (KR); Shunichi Kubota, Suwon-si (KR); Tae-hyung Kim, Seoul (KR); Seoung-jae Im, Seoul (KR)

Correspondence Address: CANTOR COLBURN LLP, 20 Church Street, 22nd Floor, Hartford, CT, 06103, US

(73) Assignees: Samsung Electronics Co., Ltd., Suwon-si (KR); Samsung Electro-mechanics Co., Ltd., Suwon-si (KR)

(21) Appl. No.: 12/803,481

(22) Filed: Jun. 28, 2010

(30) Foreign Application Priority Data
Jun. 26, 2009 (KR) 10-2009-0057715

(51) Int. Cl. H01L 33/32; C09K 11/55

(52) U.S. Cl. 257/98; 252/301.4 F; 257/E33.028

(57) ABSTRACT

A method of preparing oxynitride phosphor represented by Formula 1:

(M₍₁₋ₓ₎Euₓ)ₐSi_{b}O_{c}N_{d} Formula 1

wherein M is an alkaline earth metal; and 0<x<1, 1.8<a<2.2, 4.5<b<5.5, 0≦c<8, 0<d≦8, and 0<c+d≦8, the method including: mixing an alkaline earth metal precursor compound, an europium precursor compound, an acid, an Si₃N₄ powder, and a chelate compound to form a gel-phase product; drying the gel-phase product, sintering the gel-phase product to form a first sintered powder; grinding the first sintered powder; mixing the first sintered powder with about 20 to about 200 parts by weight of carbon, based on 100 parts by weight of the first sintered powder, to obtain a mixture of the first sintered powder and the carbon; and sintering the mixture of the first sintered powder and the carbon to provide the oxynitride phosphor.

### CROSS-REFERENCE TO RELATED APPLICATIONS

This application claims priority to Korean Patent Application No. 10-2009-0057715, filed on Jun. 26, 2009, and all the benefits accruing therefrom under 35 U.S.C. §119, the content of which in its entirety is herein incorporated by reference.

### BACKGROUND

1. Field

One or more embodiments relate to a method of preparing an oxynitride phosphor, an oxynitride phosphor obtained using the method, and a white light-emitting device including the oxynitride phosphor.

2. Description of the Related Art

A conventional optical system may include a fluorescent lamp or an incandescent lamp. Fluorescent lamps, however, cause environmental problems due to mercury (Hg) included therein. Also, such conventional optical systems have very short lifetimes and low efficiency, and thus are unsuitable for energy saving applications. Thus, there remains a need for a white light-emitting device that provides improved efficiency.

White light emitting devices can produce white light by using any one of three methods. Red, green, and blue phosphors may be excited by an ultraviolet (“UV”) light-emitting diode (“LED”) acting as a light source to produce white light; red and green phosphors may be excited by a blue LED acting as a light source to produce white light, or a yellow phosphor may be excited by a blue LED acting as a light source to produce white light.

In the white light-emitting device technology field, there remains a need for a red phosphor having high efficiency with respect to excitation by UV and blue light. Red phosphors including a nitride have been developed. However, it is difficult to produce a nitride phosphor having high efficiency in a high yield using conventional phosphor synthesis equipment and technology because most of the source materials thereof are unstable in air, the synthesis temperature is equal to or greater than 1500° C., and the synthesis pressure is equal to or greater than 10 atmospheres.

### SUMMARY

One or more embodiments include a method of preparing an oxynitride phosphor having high efficiency, the method providing a high yield under mild conditions, wherein the oxynitride phosphor is a red phosphor.

One or more embodiments include an oxynitride phosphor obtained using the method.

One or more embodiments include a white light-emitting device including the oxynitride phosphor.

Additional aspects will be set forth in part in the description which follows and, in part, will be apparent from the description.

According to one or more embodiments, a method of preparing an oxynitride phosphor represented by Formula 1:

(M₍₁₋ₓ₎Euₓ)ₐSi_{b}O_{c}N_{d} Formula 1

wherein M is an alkaline earth metal; and 0<x<1, 1.8<a<2.2, 4.5<b<5.5, 0≦c<8, 0<d≦8, and 0<c+d≦8, the method including: mixing an alkaline earth metal precursor compound, an europium (Eu) precursor compound, an acid, an Si₃N₄ powder, and a chelate compound to form a gel-phase product; drying the gel-phase product, sintering the gel-phase product to form a first sintered powder; grinding the first sintered powder; mixing the first sintered powder with about 20 to about 200 parts by weight of carbon, based on 100 parts by weight of the first sintered powder, to obtain a mixture of the first sintered powder and the carbon; and sintering the mixture of the first sintered powder and the carbon to provide the oxynitride phosphor.

The oxynitride phosphor represented by Formula 1 may include pores.

According to one or more embodiments, disclosed is an oxynitride phosphor represented by Formula 1:

(M₍₁₋ₓ₎Euₓ)ₐSi_{b}O_{c}N_{d} Formula 1

wherein M is an alkaline earth metal and 0<x<1, 1.8<a<2.2, 4.5<b<5.5, 0≦c<8, 0<d≦8, and 0<c+d≦8, the oxynitride phosphor prepared using a method including: mixing an alkaline earth metal precursor compound, an europium precursor compound, an acid, an Si₃N₄ powder, and a chelate compound to form a gel-phase product; drying the gel-phase product, sintering the gel-phase product to form a first sintered powder; grinding the first sintered powder; mixing the first sintered powder with about 20 to about 200 parts by weight of carbon, based on 100 parts by weight of the first sintered powder, to obtain a mixture of the first sintered powder and the carbon; and sintering the mixture of the first sintered powder and the carbon to provide the oxynitride phosphor.

Also disclosed is a white light-emitting device including: a light-emitting diode; and an oxynitride phosphor, the oxynitride phosphor prepared using a method that includes mixing an alkaline earth metal precursor compound, an europium precursor compound, an acid, an Si₃N₄ powder, and a chelate compound to form a gel-phase product; drying the gel-phase product, sintering the gel-phase product to form a first sintered powder; grinding the first sintered powder; mixing the first sintered powder with about 20 to about 200 parts by weight of carbon, based on 100 parts by weight of the first sintered powder, to obtain a mixture of the first sintered powder and the carbon; and sintering the mixture of the first sintered powder and the carbon to provide the oxynitride phosphor.

Also disclosed is a white light-emitting device including: a blue LED; and an oxynitride phosphor, the oxynitride phosphor prepared using a method including mixing an alkaline earth metal precursor compound, an europium precursor compound, an acid, an Si₃N₄ powder, and a chelate compound to form a gel-phase product; drying the gel-phase product, sintering the gel-phase product to form a first sintered powder; grinding the first sintered powder; mixing the first sintered powder with about 20 to about 200 parts by weight of carbon, based on 100 parts by weight of the first sintered powder, to obtain a mixture of the first sintered powder and the carbon; and sintering the mixture of the first sintered powder and the carbon to provide the oxynitride phosphor.

The oxynitride phosphor of Formula 1 may further include about 0.2 to about 3 weight percent carbon, based on the total weight of the oxynitride phosphor.

According to one or more embodiments, a white light-emitting device includes: a blue LED; and the oxynitride phosphor.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

These and/or other aspects will become apparent and more readily appreciated from the following description of the embodiments, taken in conjunction with the accompanying drawings in which:

FIG. 1 is a schematic diagram illustrating an exemplary embodiment of a gel-phase product produced using an exemplary embodiment of a method of preparing a phosphor;

FIG. 2 is a schematic flow diagram illustrating an exemplary embodiment of a method of preparing a phosphor;

FIG. 3 is a schematic view illustrating an exemplary embodiment of the structure of a white light-emitting device;

FIG. 4 is a graph of intensity (arbitrary units) versus wavelength (nanometers, m) showing the emission efficiency of phosphors obtained in Example 1 and Comparative Example 1;

FIG. 5 is a graph of intensity (arbitrary units) versus scattering angle (degrees two-theta, 2θ) showing an X-ray diffraction (“XRD”) pattern of the phosphors obtained in Example 1 and Comparative Example 1;

FIG. 6A is an emission image of the phosphor obtained in Comparative Example 2;

FIG. 6B is an emission image of the phosphor obtained in Comparative Example 3;

FIG. 6C is an emission image of the phosphor obtained in Example 1;

FIG. 7 is a graph of intensity (arbitrary units) versus wavelength (nanometers, m) showing emission efficiency of the phosphors obtained in Example 1 and Comparative Examples 2 and 3;

FIG. 8 is a graph of intensity (arbitrary units) versus wavelength (nanometers, m) showing a white light spectrum of a white phosphor according to Example 2 at a color temperature of 3,000 K; and

FIG. 9 is a graph of intensity (arbitrary units) versus wavelength (nanometers, m) showing a white light spectrum of a white phosphor according to Example 3 at a color temperature of 5,000 K.

### DETAILED DESCRIPTION

The present invention will now be described more fully with reference to the accompanying drawings, in which exemplary embodiments of the invention are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present invention.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

A method of preparing an oxynitride phosphor includes: mixing of an alkaline earth metal precursor compound, an europium (Eu) precursor compound, an acid, an Si₃N₄ powder, and a chelate compound, to form a gel-phase product;

A method of preparing an oxynitride phosphor according to an embodiment includes: mixing an alkaline earth metal precursor compound, an europium (Eu) precursor compound, an acid, an Si₃N₄ powder, and a chelate compound, to form a gel-phase product; heating, drying, and grinding the gel-phase product; sintering and grinding the gel-phase product to form a first sintered powder; and mixing the powder with about 20 to about 200 parts by weight of carbon, based on 100 parts by weight of the first sintered powder, to obtain a mixture of the first sintered powder and the carbon and sintering the mixture of the first sintered powder and the carbon to provide the oxynitride phosphor.

The method will now be described in further detail.

The alkaline earth metal precursor compound used as a starting material to form the gel-phase product may be, for example, a barium (Ba) precursor compound, a strontium (Sr) precursor compound, a potassium (Ca) precursor compound, or a mixture comprising at least one of the foregoing.

Examples of the Ba precursor compound may include BaCO₃, Ba(NO₃)₂, BaCl₂, BaO, Ba(CH₂COOH)₂, or a combination comprising at least one of the foregoing. Examples of the Sr precursor compound may include SrCO₃, Sr(NO₃)₂, SrCl₂, SrO, Sr(CH₂COOH)₂, or a combination comprising at least one of the foregoing. Examples of the Ca precursor compound may include CaCO₃, Ca(NO₃)₂, CaCl₂, CaO, Ca(CH₂COOH)₂, or a combination comprising at least one of the foregoing. These compounds may be used alone or in a combination of at least two compounds.

Examples of the Eu precursor compound used as a starting material to form the gel-state product may include Eu₂O₃, Eu(NO₃)₃, EuCl₃, or a combination comprising at least one of the foregoing. These compounds may be used alone or in a combination of at least two compounds.

The alkaline earth metal precursor compound and the Eu precursor compound, which are starting materials, are dissolved in the acid. The acid may be an inorganic acid or an organic acid, e.g., HNO₃, HCl, H₂SO₄, acetic acid, butyric acid, palmitic acid, oxalic acid, tartaric acid, or a combination comprising at least one of the foregoing. The acid may have a concentration of about 0.1 to about 10 normal (N), specifically about 0.5 to about 9 N, more specifically 1 to about 5 N, but is not limited thereto.

Next, Si₃N₄ is added to the acid in which the alkaline earth metal precursor compound and the Eu precursor compound are dissolved. Si₃N₄ may be added in powder form. Alternatively, the Si₃N₄ may be mixed with the alkaline earth metal precursor compound and the Eu precursor compound, and the mixture of the Si₃N₄, the alkaline earth metal precursor compound, and the Eu precursor compound contacted with the acid.

Next, the chelate compound is added to the mixture of the acid, the alkaline earth metal precursor compound, the Eu precursor compound, and the Si₃N₄ powder, to form a gel-phase product. Examples of the chelate compound may include citric acid, glycine, polyethylene glycol, urea, ethylenediaminetetraacetic acid (“EDTA”), or a combination comprising at least one of the foregoing.

When the chelate compound is added to and contacted with the mixture, an alkaline earth metal-chelate compound and a Eu-chelate compound are formed.

For example, the alkaline earth metal-chelate compound and the Eu-chelate compound may be formed by using SrCO₃ as the alkaline earth metal precursor compound, Eu₂O₃ as the Eu precursor compound, a nitric acid as the acid, and citric acid (C₆H₈O₇) as the chelate compound, as in Reaction Scheme 1.

SrCO₃+Eu₂O₃+HNO₃+C₆H₈O₇+Si₃N₄→

Sr²⁺-chelate compound+Eu³⁺-chelate compound+Si₃N₄+NO₃⁻ Reaction Scheme 1

The Sr²⁺-chelate compound is formed by contacting SrCO₃ with the nitric acid to form Sr²⁺, followed by contacting the Sr²⁺with the citric acid according to Reaction Scheme 2.

SrCO₃+HNO₃→Sr²⁺+NO₃⁻

Sr²⁺+C₆H₈O₇→“Sr²⁺-chelate compound” Reaction Scheme 2

The Eu³⁺-chelate compound is formed by contacting Eu₂O₃ with the nitric acid to form Eu³⁺, followed contacting the Eu³⁺ with citric acid according to Reaction Scheme 3.

Eu₂O₃+HNO₃→Eu³⁺+NO₃⁻

Eu³⁺+C₆H₈O₇→“Eu³⁺-chelate compound” Reaction Scheme 3

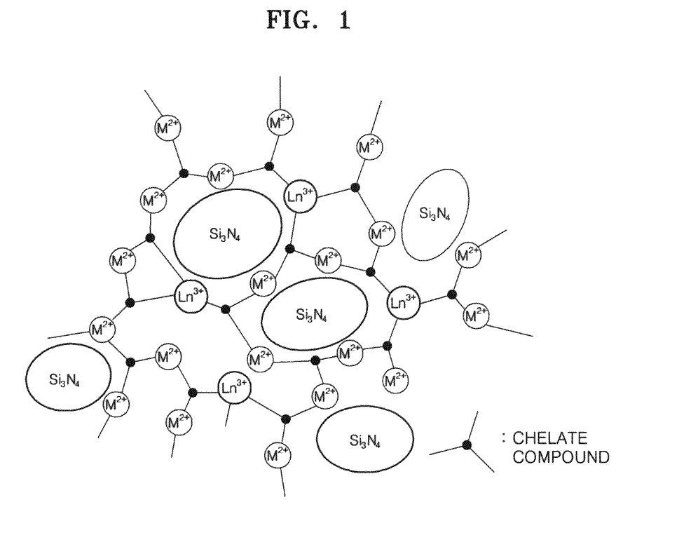

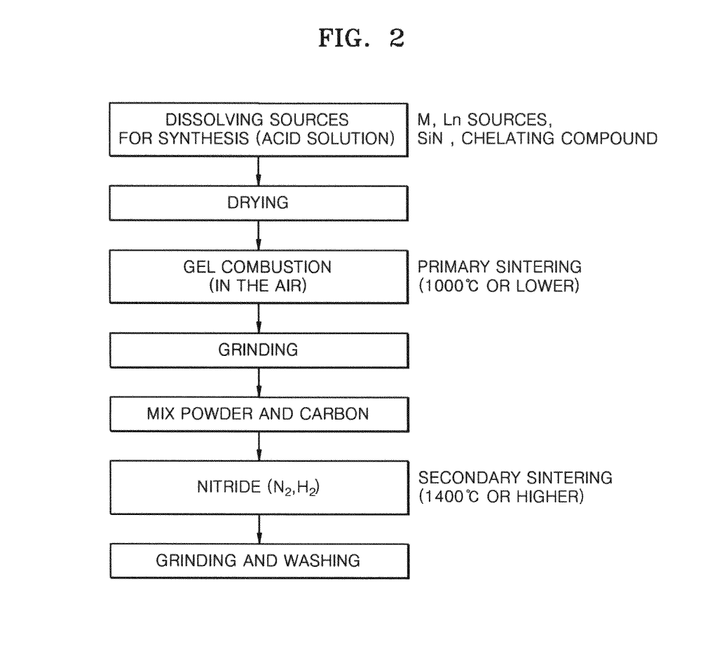

FIG. 1 illustrates a gel-phase product formed using the above-described procedure. Referring to FIG. 1, the Sr²⁺-chelate compound (e.g., M²⁺-chelate compound) and the Eu³⁺-chelate compound (e.g., Ln³⁺-chelate compound) are uniformly distributed on an atomic scale between the particles of the Si₃N₄ powder.

The gel-phase product may be formed using a chelation reaction, and the chelation reaction may be performed at a temperature of about 25 to about 100° C., specifically about 30 to about 95° C., more specifically about 35 to about 90° C. for about 10 minutes to about 2 hours, specifically about 20 to about 90 minutes, more specifically about 30 to about 80 minutes. The obtained gel-phase product may be partially or completely dried and then ground, thereby providing a ground product. In another embodiment, the obtained gel-phase product is completely dried and then ground, thereby providing a ground product.

The ground product is sintered to form a first sintered powder. The sintering may be performed in air at a temperature of about 200 to about 1,000° C., specifically about 300 to about 700° C., more specifically about 400 to about 600° C., for 0.1 to 10 hours, specifically about 0.5 to about 5 hours, more specifically about 1 to about 4 hours.

As further described above, when the gel-phase product is formed using the disclosed phosphor source materials, such as the alkaline earth metal precursor compound, the europium precursor compound, the acid, the Si₃N₄ powder, and the chelate compound, and the gel-phase product is sintered, constituent ions are uniformly distributed on an atomic scale. The uniform distribution is understood to contribute to improved crystallinity of the nitride phosphor, which has low ionic mobility, and is understood to substantially reduce or effectively prevent agglomeration of activators.

The first sintered product is ground to form a first sintered powder using a grinding method. Exemplary grinding methods include ball milling, planetary ball milling, or jet milling.

The first sintered powder is then mixed with carbon, and the mixture of the first sintered powder and the carbon is sintered. The sintering of the first sintered powder and the carbon may be performed at 1,300 to 1,800° C., specifically at 1,400 to 1,700° C., more specifically at 1,500 to 1,600° C. in a gas comprising N₂, NH₃, H₂, or a combination comprising at least one of the foregoing for about 1 to about 100 hours, specifically about 2 to about 90 hours, more specifically about 4 to about 80 hours, thereby forming an oxynitride phosphor. In an embodiment the gas is N₂, NH₃, a mixture of N₂ and NH₃, a mixture of H₂ and N₂, or a mixture of NH₃, H₂, and N₂.

The carbon used during the sintering of the first sintered powder and the carbon may combine with and remove oxygen from the source materials so that metal comprising source materials may more easily react with nitrogen. An example of this process is shown in Reaction Scheme 4, in which Sr is used as an alkaline earth metal.

6SrO+2N₂+6C+10Si₃N₅→6Sr+2N₂+6CO+10Si₃N₄→2Sr₃N₂+6CO+10Si₃N₄→3Sr₂Si₅N₈+6CO Reaction Scheme 4

In Reaction Scheme 4, C combines with the O of SrO to form CO, thereby reducing SrO to provide Sr metal, and the Sr is then bonded with nitrogen, thereby more easily forming the nitride.

The carbon may be present in an amount of about 20 to about 200 parts by weight, specifically about 40 to about 100 parts by weight, more specifically about 50 to about 90 parts by weight, base on 100 parts by weight of the first sintered powder. If the amount of the carbon is within this range, the alkaline earth metal oxide is efficiently reduced and additional undesired reactions may be substantially reduced or effectively prevented. Examples of the carbon include various carbonaceous materials, such as graphite, graphene, active carbon, carbon-containing polymers, CNT, carbon powder, carbon paper, or mixtures comprising at least one of the foregoing. These materials may be used in a powder form or by being coated with the first sintered powder.

A portion of the carbon may remain in the oxynitride phosphor, and the amount of the remaining carbon may be about 0.2 to about 3 weight percent (weight %), specifically about 0.8 to about 2.0 weight %, more specifically about 1 weight %, based on the total phosphor weight.

Optionally, a product obtained by the sintering of the mixture of the first sintered powder and the carbon may be repeatedly ground and sintered again to obtain a nitride phosphor having improved crystallinity. The additional sintering may be performed at a temperature of about 1,300 to about 1,800° C., specifically at about 1,400 to about 1,700° C., more specifically at 1,500 to 1,600° C. in gas comprising N₂, NH₃, H₂, or a combination comprising at least one of the foregoing for about 1 to about 100 hours, specifically about 2 to about 90 hours, more specifically about 4 to about 80 hours. When an additional sintering process is performed, it may be desirable to not to use carbon to reduce or prevent contamination of the phosphor powder.

Next, the product of the foregoing process may be washed to obtain an oxynitride phosphor, and the oxynitride phosphor may be in the form of a powder.

As described above, the method of preparing an oxynitride phosphor according to an embodiment may be performed under mild conditions using stable starting materials, and thus, is suitable for commercial applications. A commercially available method of preparing a nitride-based phosphor uses high temperature and a high-pressure nitrogen atmosphere. However, the disclosed method of preparing an oxynitride phosphor can be performed without using a high temperature or a high-pressure nitrogen atmosphere, thus special equipment that is designed to endure a high-temperature and high-pressure process may be avoided. Moreover, the disclosed method of preparing an oxynitride phosphor is environmentally friendly because environmentally damaging materials are not used.

Because phosphor precursor compounds are gelated and then the resulting gel product is sintered, constituent ions are uniformly distributed, and thus a phosphor having excellent crystallinity is formed and a uniform ionic distribution is obtained despite low ionic mobility of the phosphor. In addition, use of a small amount of carbon can reduce oxide source materials, and more nitrogen is combined with the reduced source materials, and thus, nitride formation is improved.

One or more embodiments include an oxynitride phosphor obtained using the above-described method and which may be represented by Formula 1 below:

(M₍₁₋ₓ₎Euₓ)ₐSi_{b}O_{c}N_{d} Formula 1

wherein M is an alkaline earth metal; and 0<x<1, 1.8<a<2.2, 4.5<b<5.5, 0≦c<8, 0<d≦8, and 0<c+d≦8.

An example of the oxynitride phosphor of Formula 1 may include (Sr₁₋ₓEuₓ)₂Si₅N₈, wherein 0≦x≦1.

The oxynitride phosphor of Formula 1 may emit red light upon excitation, thus may be referred to as a red phosphor, is excited under ultraviolet (“UV”) or blue light, and exhibits high red light-emission efficiency. Thus, both a UV light-emitting diode (“UV-LED”) or a blue-LED, or a combination comprising at least one of the foregoing, can be used as an excitation source in a white light-emitting device including the oxynitride phosphor of Formula 1.

The oxynitride phosphor of Formula 1 effectively overcomes various problems of commercially available red phosphors. For example, the oxynitride phosphor of Formula 1 has a very high thermal activation energy related to quenching because a light emission activator binds with nitrogen, thus reducing emission loss for red light, which results in high red light-emission efficiency. Moreover, the oxynitride phosphor is a material capable of overcoming all the problems of commercially available red phosphors, i.e., sensitivity to moisture in air, an undesired reaction with a binder, and poor thermal durability, and thus is very useful as a red phosphor for use in a white light-emitting device.

Therefore the oxynitride phosphor of Formula 1 is very suitable for use in white light-emitting devices emitting white light by combining red, green, and blue phosphors, which emit red, green, and blue light using a UV-LED as a light source or by exciting red and green phosphors using a blue-LED as a light source. Such white light-emitting devices produce a desirable white light with high emission efficiency.

One or more embodiments include a white light-emitting device including: an LED; and the oxynitride phosphor of Formula 1 prepared using the method disclosed above. The LED may be a UV-LED or a blue light-emitting diode. The UV-LED may be used as an excitation light source, which emits an excitation light having electromagnetic waves with a wavelength in an ultra-violet or near-ultraviolet ray region. In the disclosed white light-emitting device, the wavelength of the excitation light of the UV-LED may be about 390 to about 460 nanometers (nm), specifically about 395 to about 455 nm, more specifically about 400 to about 450.

The white light-emitting device may further include a blue phosphor, a green phosphor, or a combination comprising at least one of the foregoing.

The blue phosphor may include (Sr,Ba,Ca)₅(PO₄)₃Cl:Eu²⁺; BaMg₂Al₁₆O₂₇:Eu²⁺; Sr₄Al₁₄O₂₅:Eu²⁺; BaAl₈O₁₃:Eu²⁺; (Sr,Mg,Ca,Ba)₅(PO₄)₃Cl:Eu²⁺; BaMgAl₁₀O₁₇:Eu²⁺; Sr₂Si₃O₈. 2SrCl₂:Eu²⁺, or a combination comprising at least one of the foregoing.

The green phosphor may include (Ba,Sr,Ca)₂SiO₄:Eu²⁺; Ba₂MgSi₂O₇:Eu²⁺; Ba₂ZnSi₂O₇:Eu²⁺; BaAl₂O₄:Eu²⁺; SrAl₂O₄:Eu²⁺; BaMgAl₁₀O₁₇:Eu²⁺, Mn²⁺; or BaMg₂Al₁₆O₂₇:Eu²⁺,Mn²⁺, or a combination comprising at least one of the foregoing.

The emission peak wavelength of the oxynitride phosphor, e.g., a red phosphor, may be about 610 to about 650 nm, specifically about 615 to about 645 nm, more specifically about 620 to about 640 nm. The emission peak wavelength of the green phosphor may be about 510 to about 560 nm, specifically about 515 to about 555 nm, more specifically about 520 to about 550 nm. The emission peak wavelength of the blue phosphor may be about 440 to about 460 nm, specifically about 445 to about 455 nm, more specifically about 450 nm.

One or more embodiments include a white light-emitting device including: a blue LED; and the oxynitride phosphor of Formula 1, which is obtained by using the method disclosed above. The blue LED may be used as an excitation light source for emitting an excitation light having a wavelength of about 420 to about 480 nm, specifically about 425 to about 475 nm, more specifically about 430 to about 470 nm.

The white light-emitting device may further include a green phosphor.

The green phosphor may include (Ba,Sr,Ca)₂SiO₄:Eu²⁺; Ba₂MgSi₂O₇:Eu²⁺; Ba₂ZnSi₂O₇:Eu²⁺; BaAl₂O₄:Eu²⁺; SrAl₂O₄:Eu²⁺; BaMgAl₁₀O₁₇:Eu²⁺, Mn²⁺; BaMg₂Al₁₆O₂₇:Eu²⁺,Mn²⁺, or a combination comprising at least one of the foregoing. The emission peak wavelength of the oxynitride phosphor, e.g., a red phosphor, may be about 610 to about 650 nm, specifically about 615 to about 645 nm, more specifically about 620 to about 640 nm. The emission peak wavelength of the green phosphor may be about 510 to about 560 nm, specifically about 515 to about 555 nm, more specifically about 520 to about 550 nm.

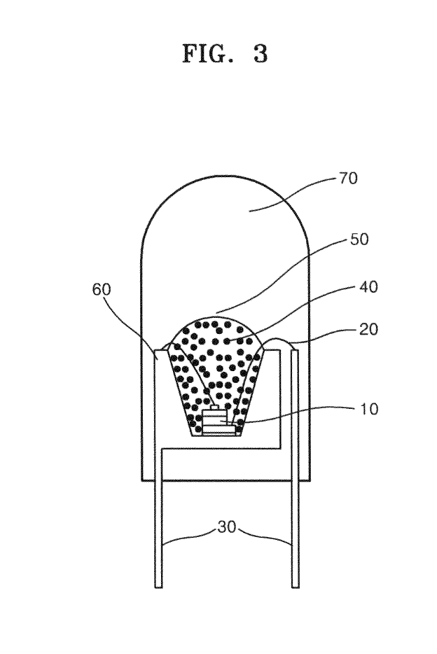

FIG. 3 is a schematic view illustrating an exemplary embodiment of the structure of a white light-emitting device. The white light-emitting device illustrated in FIG. 3 is a polymer lens type, surface-mounted LED. The polymer lens may comprise an epoxy, or a polymerization product thereof.

Referring to FIG. 3, a UV LED chip 10 is die-bonded to an electric lead line 30 via a gold wire 20, and an epoxy mold layer 50 is formed (e.g., disposed) on the UV LED chip 10 using a phosphor composition 40, which including an oxynitride phosphor as disclosed above. A reflective film coated with aluminum, silver, or a combination comprising at least one of the foregoing is formed (e.g., disposed) on an inner surface of a mold 60 in order to reflect light upward from the UV LED chip 10 and to limit the epoxy of the epoxy mold layer 50 to an appropriate amount.

An epoxy dome lens 70 is formed (e.g., disposed) above the epoxy mold layer 50. The shape of the epoxy dome lens 70 may vary according to a desired orientation angle.

The LED used in the disclosed white light-emitting device is not limited to the structure illustrated in FIG. 3. Other structures, e.g., a phosphor-mounted LED, a lamp-type LED, or a PCB-type surface-mounted LED may also be used.

In another embodiment, the oxynitride phosphor of Formula 1, which is prepared using the above-described method, may be applied to a lamp such as a mercury lamp or a xenon lamp, or a photoluminescent liquid crystal display (“PLLCD”), in addition to a light-emitting device as disclosed above.

Hereinafter, an embodiment is further described in detail with reference to the following examples. These examples are not intended to limit the purpose or scope of the disclosed embodiments.

### Example 1

A 6.3 gram (g) amount of SrCO₃, 0.15 g of Eu₂O₃, 5.0 g of Si₃N₄, and 4.8 g of citric acid were dissolved in 50 milliliters (ml) of 10% HNO₃. The solution was heated at 100° C. for about 2 hours, and completely dried and ground. The ground powder was placed in an alumina reaction container, heated at 700° C. in air for 1 hour (sintering of the gel-phase product) and ground by using an agate mortar to obtain 10.2 g of a first sintered powder. The first sintered powder was mixed with 5 g of carbon and placed in an alumina crucible. The alumina crucible containing the mixture was placed in an electrical furnace and heated at 1600²C for 10 hours (sintering of the mixture of the first sintered powder and the carbon) while a mixed gas of 10% H₂ and 90% N₂ flowed through the furnace. The carbon was used to reduce the Sr oxide and the Eu oxide. The product obtained from the sintering of the mixture of the first sintered powder and the carbon was subjected to furnace cooling, ground using an agate mortar, washed three times with distilled water, and dried in an oven, thereby obtaining a (Sr_{0.98}Eu_{0.02})_{1.88}Si₅O_{0.24}N_{7.76} red phosphor.

A mass ratio of oxygen to nitrogen in the (Sr_{0.98}Eu_{0.02})_{1.88}Si₅O_{0.24}N_{7.76} red phosphor was measured using a LECO TC400 oxygen/nitrogen analyzer. A mole ratio of oxygen to all the anions (nitrogen and oxygen, (O/(N+O)) of the (Sr_{0.98}Eu_{0.02})_{1.88}Si₅O_{0.24}N_{7.76} red phosphor was as low as 3.1%. Thus, it was identified that the method described above is suitable for synthesizing high quality nitride phosphors.

Emission characteristics of the obtained red phosphor were visually identified primarily by using a 365-nm UV lamp and were measured through excitation at 400 nm using a Hitachi F7000 spectrometer.

### Comparative Example 1

A 6.3 g amount of SrCO₃, 5 g of Si₃N₄ 5 g, and 0.15 g of Eu₂O₃ were mixed for 1 hour by using an agate mortar. The mixed powder was mixed with 5 g of carbon and placed in an alumina crucible. The alumina crucible containing the mixture was placed in an electrical furnace and heated at 1600²C for 10 hours while a mixed gas of 10% H₂ and 90% N₂ flowed through the furnace. The resulting product was subjected to furnace cooling, ground by using an agate mortar, and washed three times with distilled water, thereby obtaining a (Sr_{0.98}Eu_{0.02})_{1.845}Si₅O_{0.31}N_{7.69} phosphor. Emission characteristics of the obtained phosphor were measured through excitation at 400 nm using a Hitachi F7000 spectrometer.

### Comparative Example 2

A phosphor was prepared in the same manner as in Example 1, except that carbon was not used. The obtained phosphor was SrSi₂O₂N₂:Eu²⁺, and emission characteristics of the phosphor were visually identified primarily by using a 365-nm UV lamp and were measured through excitation at 400 nm using a Hitachi F7000 spectrometer.

### Comparative Example 3

A phosphor was prepared in the same manner as in Example 1, except that the amount of carbon used was 0.5 g. The obtained phosphor was a mixture including SrSi₂O₂N₂:Eu²⁺ as a main phase and Sr₂Si₅N₈:Eu²⁺. Emission characteristics of the obtained phosphor were visually identified by using a 365-nm UV lamp and were measured through excitation at 400 nm using a Hitachi F7000 spectrometer.

### Example 2

A phosphor combination was prepared by using 0.5 g of (Sr_{0.98}Eu_{0.02})_{1.88}Si₅O_{0.24}N_{7.76} prepared according to Example 1 as a red phosphor, 1.3 g of Sr₅(PO₄)₃Cl:Eu²⁺ as a blue phosphor, and 0.55 g of (Sr,Ba)₂SiO₄:Eu²⁺ as a green phosphor. The phosphor combination emitted a 3000 K white light when exposed to an excitation light having a wavelength of 400 nm.

### Example 3

A phosphor combination was prepared by using 0.5 g of (Sr_{0.98}Eu_{0.02})_{1.88}Si₅O_{0.24}N_{7.76} prepared according to Example 1 as a red phosphor, 1.3 g of Sr₅(PO4)₃Cl:Eu²⁺ as a blue phosphor, and 0.55 g of (Sr,Ba)₂SiO₄:Eu²⁺ as a green phosphor. The phosphor combination emitted a 5000 K white light when exposed to an excitation light having a wavelength of 400 nm.

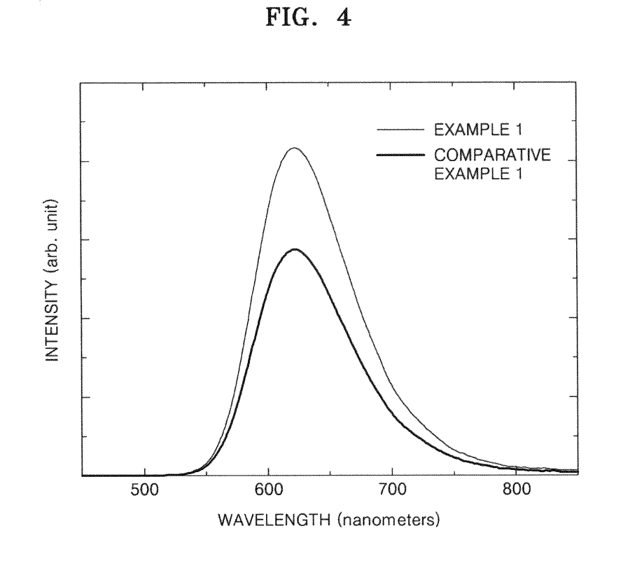

FIG. 4 is a graph of intensity (arbitrary units) versus wavelength (nanometers, m) showing the emission peaks of the phosphors obtained in Example 1 and Comparative Example 1. The phosphor prepared according to Example 1, in which gel combustion was applied as a pre-treatment for the solid-phase synthesis, had about 40% higher emission efficiency than the phosphor prepared according to Comparative Example 1, in which a simple solid-phase synthesis was performed.

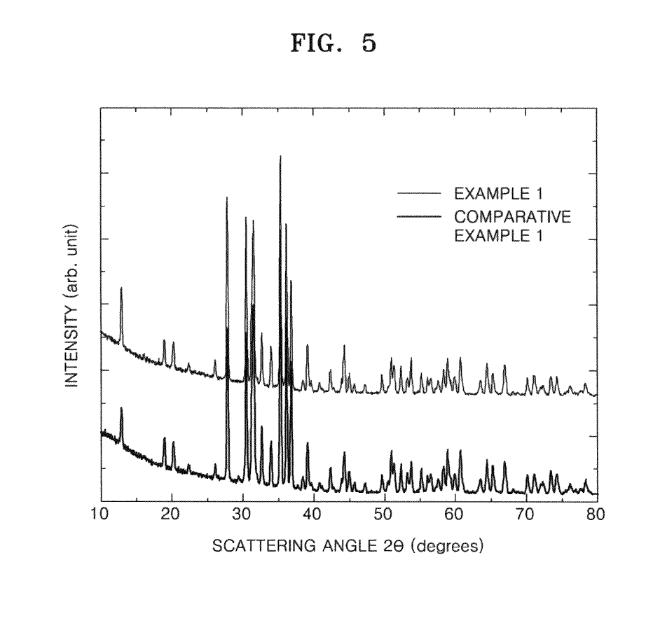

FIG. 5 is a graph of intensity (arbitrary units) versus scattering angle (degrees two-theta, 2θ) showing an X-ray diffraction (“XRD”) of the Sr₂Si₅N₈:Eu²⁺ phosphors obtained in Example 1 and Comparative Example 1. Referring to FIG. 5, the Sr₂Si₅N₈:Eu²⁺ phosphors have similar overall phase profiles to each other and very different emission efficiencies from each other. When gel combustion is performed as a pretreatment process, more uniform ionic distribution is obtained and fewer defects are formed than when only a solid-phase synthesis is performed.

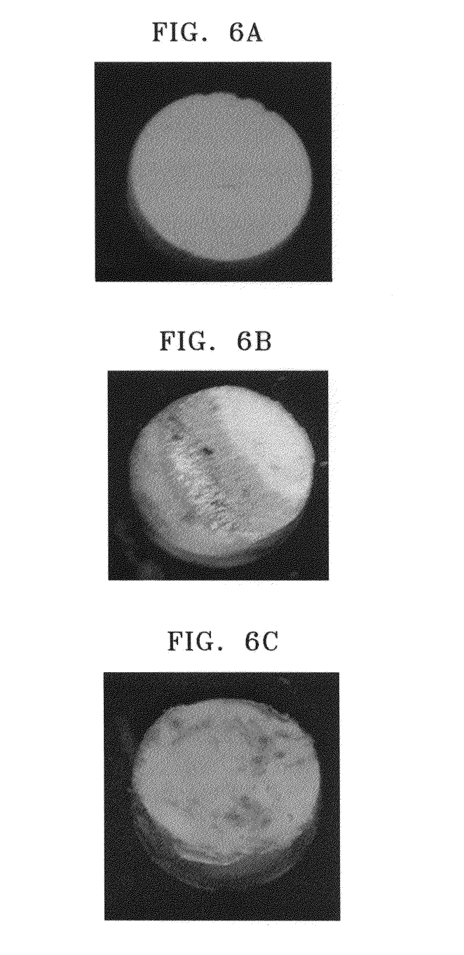

FIGS. 6A through 6C are photographic images of the phosphors prepared according to Example 1, Comparative Example 2, and Comparative Example 3 when exposed to an excitation light having a wavelength of 365 nm. The phosphor prepared according to Example 1, shown in FIG. 6C, emitted pure red light, the phosphor prepared according to Comparative Example 2, shown in FIG. 6A, emitted pure green light from emission by SrSi₂O₂N₂:Eu²⁺, and the phosphor prepared according to Comparative Example 3, shown in FIG. 6B, emitted red and green light from emission by SrSi₂O₂N₂:Eu²⁺ and Sr₂Si₅N₈:Eu²⁺, wherein the amount of Sr₂Si₅N₈:Eu²⁺ used was relatively small.

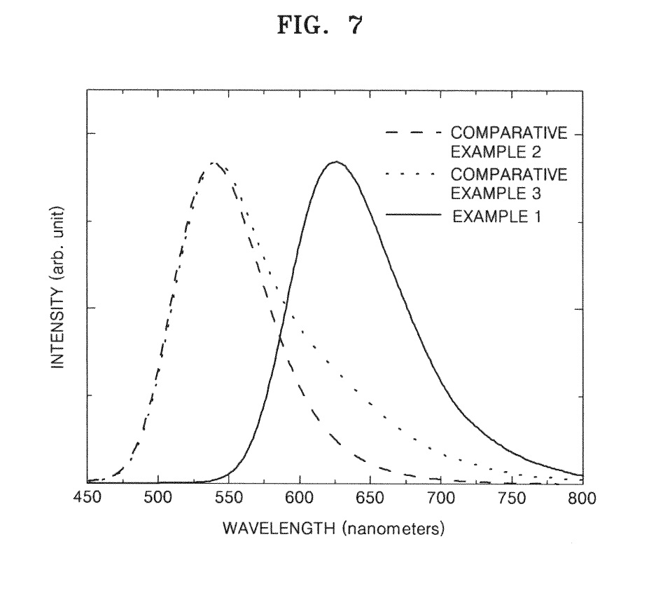

FIG. 7 is a graph of intensity (arbitrary units) versus wavelength (nanometers, m) showing emission spectra of the phosphors of Example 1 and Comparative Examples 2 and 3 when exposed to an excitation light having a wavelength of 400 nm. Referring to FIG. 7, in the case of Comparative Example 2, an emission spectrum of only SrSi₂O₂N₂:Eu²⁺ was obtained, and in the case of Comparative Example 3, in which a small amount of Sr₂Si₅N₈:Eu²⁺ was added to SrSi₂O₂N₂:Eu²⁺, an emission spectrum of SrSi₂O₂N₂:Eu²⁺ and Sr₂Si₅N₈:Eu²⁺ was obtained.

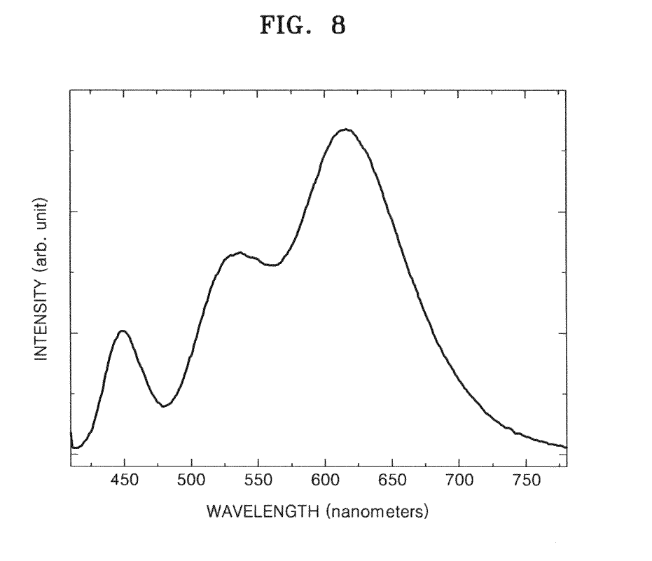

FIG. 8 is a graph of intensity (arbitrary units) versus wavelength (nanometers, m) showing a white light (3,000 K) spectrum of the phosphor of Example 2, when excited with an excitation light having a wavelength of 400 nm using a Hitachi F7000 spectrometer.

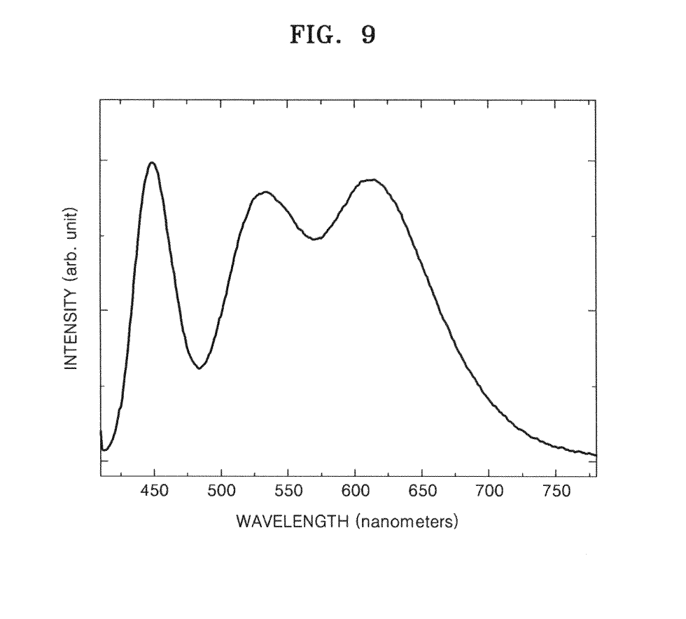

FIG. 9 is a graph of intensity (arbitrary units) versus wavelength (nanometers, m) showing a white light (5,000 K) spectrum of the phosphor of Example 3, when excited at 400 nm using a Hitachi F7000 spectrometer.

According to the disclosed method of preparing an oxynitride phosphor, the oxynitride red phosphor can be synthesized in a high yield by performing gel combustion as a pretreatment process of a solid-phase synthesis, sintering a gel combustion product, reducing with carbon, and performing nitridation.

The method is performed under mild conditions using stable starting materials and is environmentally friendly, and thus, is useful for a commercial application. An oxynitride phosphor prepared using the method produces red light suitable for use in UV-LED and blue-LED type white light-emitting devices and achieves good efficiency.

It should be understood that the exemplary embodiments described therein should be considered in a descriptive sense only and not for purposes of limitation. Descriptions of features or aspects within each embodiment should be considered as available for other similar features or aspects in other embodiments.

What is claimed is:

1. A method of preparing an oxynitride phosphor represented by Formula 1:
(M₍₁₋ₓ₎Euₓ)ₐSi_{b}O_{c}N_{d} Formula 1
wherein M is an alkaline earth metal and 0<x<1, 1.8<a<2.2, 4.5<b<5.5, 0≦c<8, 0<d≦8, and 0<c+d≦8, the method comprising:
mixing an alkaline earth metal precursor compound, an europium precursor compound, an acid, an Si₃N₄ powder, and a chelate compound to form a gel-phase product;
drying the gel-phase product,
sintering the gel-phase product to form a first sintered powder;
grinding the first sintered powder;
mixing the first sintered powder with about 20 to about 200 parts by weight of carbon, based on 100 parts by weight of the first sintered powder, to obtain a mixture of the first sintered powder and the carbon; and
sintering the mixture of the first sintered powder and the carbon to provide the oxynitride phosphor.

2. The method of claim 1, wherein the carbon is present in an amount of about 40 to about 200 parts by weight, based on 100 parts by weight of the first sintered powder.

3. The method of claim 1, wherein the sintering of the mixture of the first sintered powder and the carbon is performed at a temperature of about 1,400 to about 1,800° C.

4. The method of claim 1, wherein M comprises Ba, Sr, Ca, or a combination comprising at least one of the foregoing.

5. The method of claim 1, wherein the oxynitride phosphor of Formula 1 comprises (Sr₍₁₋ₓ₎Euₓ)ₐSi_{b}O_{c}N_{d}, wherein 0<x≦0.1, 1.8<a<2.2, 4.5<b<5.5, 0<c<0.5, and 0<d≦8.

6. The method of claim 1, wherein the oxynitride phosphor of Formula 1 comprises (Sr₍₁₋ₓ₎Euₓ)ₐSi_{b}O_{c}N_{d}, where 1.8<a<2.2, 4.5<b<5.5, c=0, 0<d≦8, and 0<x≦0.1.

7. The method of claim 1, wherein the oxynitride phosphor of Formula 1 comprises (Sr₍₁₋ₓ₎Euₓ)₂Si₅N₈, wherein 0<x≦0.1.

8. The method of claim 1, wherein the oxynitride phosphor of Formula 1 further comprises about 0.2 to about 3 weight percent carbon, based on the total weight of the oxynitride phosphor.

9. The method of claim 1, wherein the alkaline earth metal precursor compound comprises BaCO₃, BaO, Ba(NO₃)₂, BaCl₂, Ba(CH₂COOH)₂, SrCO₃, SrO, Sr(NO₃)₂, SrCl₂, Sr(CH₂COOH)₂, CaCO₃, CaO, Ca(NO₃)₂, CaCl₂, Ca(CH₂COOH)₂, or a combination comprising at least one of the foregoing.

10. The method of claim 1, wherein the Eu precursor compound comprises Eu₂O₃, Eu(NO₃)₃, EuCl₃, or a combination comprising at least one of the foregoing.

11. The method of claim 1, wherein the acid comprises hydrochloric acid, sulfuric acid, nitric acid, acetic acid, butyric acid, palmitic acid, oxalic acid, tartaric acid, or a combination comprising at least one of the foregoing.

12. The method of claim 1, wherein the chelate compound comprises citric acid, glycine, urea, ethylenediaminetetraacetic acid, or a combination comprising at least one of the foregoing.

13. The method of claim 1, wherein the sintering of the gel-phase product is performed at a temperature of about 200 to about 1,000° C. in air.

14. The method of claim 1, wherein the sintering of the mixture of the first sintered powder and the carbon is performed at a temperature of about 1,300 to about 2,000° C. for about 1 to about 100 hours in a gas comprising N₂, NH₃, H₂, or a combination comprising at least one of the foregoing.

15. An oxynitride phosphor represented by Formula 1:
(M₍₁₋ₓ₎Euₓ)ₐSi_{b}O_{c}N_{d} Formula 1
wherein M is an alkaline earth metal and 0<x<1, 1.8<a<2.2, 4.5<b<5.5, 0≦c<8, 0<d≦8, and 0<c+d≦8, the oxynitride phosphor prepared using a method comprising:
mixing an alkaline earth metal precursor compound, an europium precursor compound, an acid, an Si₃N₄ powder, and a chelate compound to form a gel-phase product;
drying the gel-phase product,
sintering the gel-phase product to form a first sintered powder;
grinding the first sintered powder;
mixing the first sintered powder with about 20 to about 200 parts by weight of carbon, based on 100 parts by weight of the first sintered powder, to obtain a mixture of the first sintered powder and the carbon; and
sintering the mixture of the first sintered powder and the carbon to provide the oxynitride phosphor.

16. A white light-emitting device comprising:
a light-emitting diode; and
an oxynitride phosphor of claim 15.

17. The white light-emitting device of claim 17, wherein the light-emitting diode is a UV light-emitting diode.

18. The white light-emitting device of claim 17, further comprising at least one of a blue phosphor and a green phosphor.

19. The white light-emitting device of claim 16, the light-emitting diode is a blue light-emitting diode.

20. The white light-emitting device of claim 18, further comprising a green phosphor.
